(19) United States
(12) Patent Application Publication
(10) Pub. No.: US 2025/0256617 A1
(43) Pub. Date: Aug. 14, 2025

(54) VEHICLE

(71) Applicant: TOYOTA JIDOSHA KABUSHIKI KAISHA, Toyota-shi (JP)

(72) Inventor: Shinji ICHIKAWA, Nagoya-shi (JP)

(73) Assignee: TOYOTA JIDOSHA KABUSHIKI KAISHA, Toyota-shi (JP)

(21) Appl. No.: 18/949,275

(22) Filed: Nov. 15, 2024

(30) Foreign Application Priority Data
Feb. 14, 2024 (JP) 2024-020158

(51) Int. Cl. B60L 58/10; B60L 50/60; B60L 53/80; G01R 31/52; H01M 6/50

(52) U.S. Cl. CPC B60L 58/10; B60L 50/60; G01R 31/52; H01M 6/5083; B60L 53/80; B60L 2210/12

(57) ABSTRACT

ECU executes a process including a step of determining that there is an electric leakage in the battery pack when the resistance value of the insulation resistance of the battery pack of each battery pack is equal to or less than the threshold value (NO in S102), and a step of determining that there is an electric leakage in the vehicle body (S106) when the resistance value of the insulation resistance of any of the battery packs is greater than the threshold value (YES in S102) and the resistance value of the insulation resistance of the vehicle body is equal to or less than the threshold value (S114).

### CROSS-REFERENCE TO RELATED APPLICATION

This application claims priority to Japanese Patent Application No. 2024-020158 filed on Feb. 14, 2024, incorporated herein by reference in its entirety.

### BACKGROUND

### 1. Technical Field

The present disclosure relates to a vehicle including a replaceable battery.

### 2. Description of Related Art

Japanese Unexamined Patent Application Publication No. 2015-082350 (JP 2015-082350 A), for example, discloses a configuration in which a battery management device provided in a battery pack is communicably connected to various electronic control devices on the vehicle side via a Controller Area Network (CAN) communication network and transmits information that indicates a result of detecting an electric leakage and the like.

### SUMMARY

In a vehicle equipped with a replaceable battery, however, a plurality of electric leakage detection devices that detects an electric leakage may be mounted on the battery side and the vehicle side, for example. Therefore, when detection of an electric leakage is performed in parallel by the electric leakage detection devices, there is a case where an electric leakage cannot be appropriately detected due to interference with each other.

The present disclosure has been made to address the above issue, and an object thereof is to provide a vehicle that appropriately detects an electric leakage when a plurality of electric leakage detection devices is mounted.

A certain aspect of the present disclosure provides a vehicle including: a vehicle body; a battery detachable from the vehicle body; a first detection device provided in the battery to detect presence or absence of an electric leakage; and a second detection device provided on the vehicle body to detect presence or absence of an electric leakage. Each of the first detection device and the second detection device detects the presence or absence of the electric leakage when in a first state in which the battery and an electric device of the vehicle body are electrically disconnected from each other. The second detection device detects the presence or absence of the electric leakage when in a second state in which the battery and the electric device are electrically connected to each other.

In this way, the first detection device and the second detection device detect the presence or absence of an electric leakage in each of the battery and the electric device of the vehicle body in the first state, and the second detection device detects the presence or absence of an electric leakage in the battery and the electric device of the vehicle body in the second state. Therefore, detection of an electric leakage is executed according to the state of attachment and detachment of the battery, making it possible to specify the location where an electric leakage occurs while avoiding interference. Thus, it is possible to appropriately detect an electric leakage when a plurality of electric leakage detection devices is mounted.

In a certain embodiment, the second detection device may detect the presence or absence of the electric leakage when in the second state and while detection of the presence or absence of the electric leakage by the first detection device is stopped.

In this way, it is possible to detect an electric leakage using the second detection device by avoiding interference of other detection devices.

In another certain embodiment, the vehicle may further include a control device that acquires information about a detection result of the presence or absence of the electric leakage from the first detection device and the second detection device. When in the second state, the control device may acquire an execution status of detection of the electric leakage. The control device may either request detection of the electric leakage by the first detection device or request stop of detection of the electric leakage using the acquired execution status.

In this way, it is possible to detect an electric leakage with high accuracy by avoiding interference between the electric leakage detection by the first detection device and the electric leakage detection by the second detection device.

According to the present disclosure, it is possible to provide a vehicle that appropriately detects an electric leakage when a plurality of electric leakage detection devices is mounted.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram illustrating an example of a configuration of a vehicle according to the present embodiment;

FIG. 2 is a diagram illustrating an example of a configuration of a battery replacement system for replacing a battery pack;

FIG. 3 is a flowchart illustrating an example of a method of replacing a battery pack;

FIG. 4 is a flowchart illustrating an example of the electric leakage determination process of FIG. 3;

FIG. 5 is a flow chart illustrating an exemplary leakage determination process at the time of Ready-Off; and

FIG. 6 is a flowchart illustrating an example of a process of setting a state of electric leakage detection.

### DETAILED DESCRIPTION OF EMBODIMENTS

Hereinafter, an embodiment of the present disclosure will be described in detail with reference to the drawings. It should be noted that the same or corresponding parts in the drawings are designated by the same reference characters and repetitive description will be omitted.

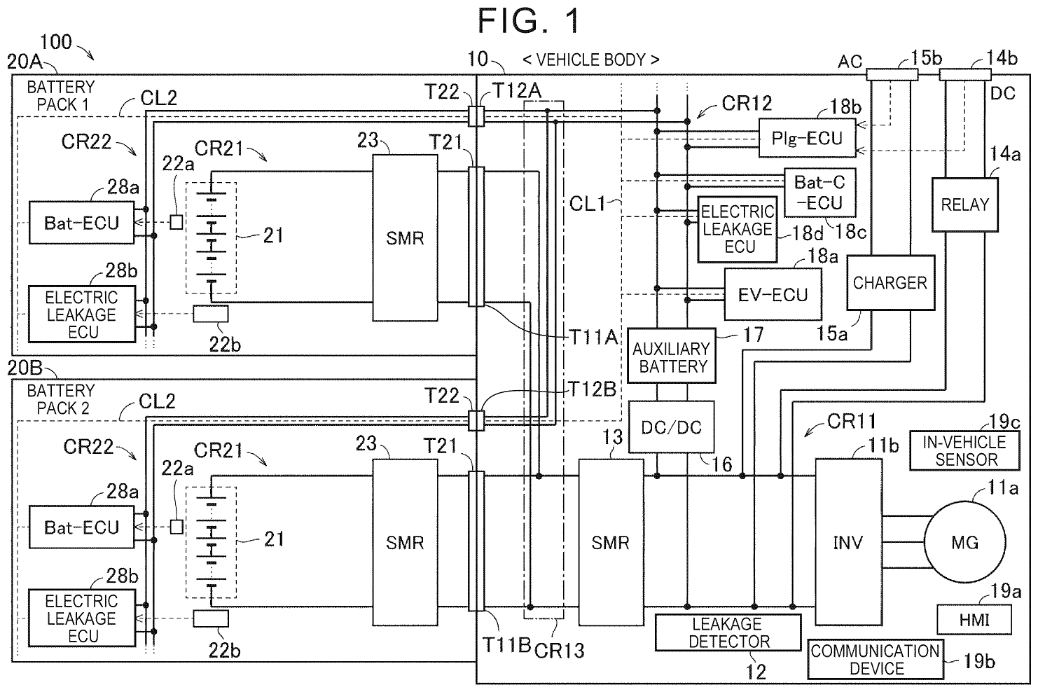

FIG. 1 is a diagram illustrating an example of a configuration of a vehicle 100 according to the present embodiment. Referring to FIG. 1, a vehicle 100 includes a vehicle body 10 and a battery-pack 20A, 20B. The vehicle body 10 is a part of the vehicle 100 other than the battery-pack 20A, 20B. The vehicle body 10 includes a vehicle driving device serving as a driving source. Vehicle-driven devices include Motor Generator (MG) 11a and inverters 11b. The vehicle driving device is configured to drive the vehicle 100 using the electric power outputted from each of the battery-pack 20A, 20B. The battery-pack 20A and 20B are configured to be connectable in parallel to the inverter 11b. Vehicle 100 is, for example, a battery electric vehicle that does not include an internal combustion engine. However, the present disclosure is not limited thereto, and the vehicles 100 may be plug-in hybrid electric vehicle including an internal combustion engine or other electrified vehicle. In this embodiment, since the battery pack 20A and 20B have the same configuration, they are referred to as “battery pack 20” in the following cases where they are not distinguished from each other.

The vehicle body 10 includes a circuit CR11 and a CR12. The battery-pack 20 includes a circuit CR21 and a circuit CR22. The circuit CR12 includes an auxiliary battery 17. The circuit CR 21 includes a battery 21. The battery 21 is, for example, a secondary battery such as a lithium ion battery, a nickel metal hydride battery, or a sodium ion battery. The type of the secondary battery may be a liquid secondary battery or an all-solid secondary battery. A plurality of secondary batteries may form a battery pack. The auxiliary battery 17 corresponds to a low-voltage power supply that outputs power at a voltage lower than the voltage of the battery 21. A DC/DC converter 16 is provided between the circuit CR11 and the circuit CR12.

The circuit CR11 in the vehicle body 10 includes a MG 11a, an inverter 11b, a DC charge relay 14a, a DC inlet 14b, a AC charger 15a, and a AC inlet 15b. Further, the circuit CR11 is provided with a leakage detector 12. The circuit CR21 in the battery pack 20 is provided with a Battery Management System (BMS) 22a and a leakage detector 22b.

The vehicle body 10 further includes a terminal T11A to which the battery pack 20A is detachable, and a terminal T11B to which the battery pack 20B is detachable. The vehicle body 10 further includes a parallel circuit CR 13 that connects the terminal T11A and the terminal T11B in parallel, and a System Main Relay (SMR) 13 disposed between the parallel circuit CR 13 and the vehicle driving device (inverter 11b). The circuit CR11 is connected to each of the terminals T11A, T11B via SMR 13 and the parallel circuit CR13. Each of the battery-pack 20A, 20B includes a terminal T21 to which the vehicle body 10 is detachable, and a SMR 23 disposed between the terminal T21 and the circuit CR21. The circuit CR21 is connected to the terminal T21 via a SMR 23.

The terminal T21 of the battery-pack 20A is connected to the terminal T11A of the vehicle body 10. In the battery pack 20A, SMR 23 of the battery pack 20A is disposed between the terminal T21 and the battery 21. The terminal T21 of the battery-pack 20B is connected to the terminal T11B of the vehicle body 10. In the battery pack 20B, SMR 23 of the battery pack 20B is disposed between the terminal T21 and the battery 21. The relays enable easy and appropriate switching of connection/disconnection between the inverter 11b and each of the battery-pack 20A, 20B.

The vehicle body 10 further includes a terminal T12A to which the battery pack 20A is detachable, and a terminal T12B to which the battery pack 20B is detachable. The circuit CR12 in the vehicle body 10 is connected to each of the terminals T12A, T12B via a parallel circuit CR13. The parallel-circuit CR13 connects the terminal T12A and the terminal T12B in parallel. A communication line CL1 (a broken line in FIG. 1) in the vehicle body 10 is also connected to each of the terminal T12A, T12B. Each of the battery-pack 20A, 20B further includes a terminal T22. In each of the battery-pack 20A, 20B, the circuit CR22 and the communication line CL2 (the broken line in FIG. 1) are connected to the terminal T22.

The auxiliary battery 17 supplies electric power for driving auxiliary machines mounted on the vehicle 100. The auxiliary battery 17 outputs DC power to the circuit CR12. The circuit CR12 further includes ECUs 18a, 18b, 18c, 18d in addition to the auxiliary battery 17. The circuit CR22 further includes ECUs 28a, 28b. The auxiliary battery 17 supplies power to each of 18d, ECUs 28a, 28b from, for example, the ECU 18a connected to the low-voltage power supply line.

ECU 18a corresponds to a control device (EV-ECU) that controls various types of control related to the vehicles 100. ECU 18b corresponds to a control device (Plg-ECU) that detects the status of each of DC inlet 14b and AC inlet 15b. ECU 18c corresponds to a control device (Bat-C-ECU) that controls DC charge-relay 14a and AC charger 15a. ECU 18d corresponds to a control device (first leakage ECU) that monitors the electric leakage status of the circuit CR11. ECU 28a corresponds to a control device (Bat-ECU) that monitors the status of the battery 21 and controls SMR 23. ECU 28b corresponds to a control device (second leakage ECU) that monitors the electric leakage status of the circuit CR21.

ECU includes a processor and a storage device. The storage device is configured to be able to save the stored information. In addition to the program, the storage device stores various kinds of information used in the program. In this embodiment, various kinds of control are executed by the processor executing a program stored in the storage device. However, these processes may be executed only by hardware (electronic circuit) without using software.

In the vehicle 100, ECUs are communicatively connected to each other via an in-vehicle network (e.g., a CAN). ECU 18a obtains information from other ECUs, controls the inverter 11b, DC/DC converters 16 and SMR 13, 23, and sends control commands to ECU 18c and ECU 28a.

The leakage detector 12 detects a leakage condition (e.g., an isolation resistor) of the circuit CR11, and outputs the detected condition to ECU 18d. BMS 22a detects the condition (current, voltage, temperature, etc.) of the battery 21, and outputs the detected condition to ECU 28a. The leakage detector 22b detects a leakage condition of the circuit CR21, and outputs the detected condition to ECU 28b. ECU 18a acquires information indicating a battery state and a leakage state from ECUs 18d, 28a, 28b.

DC/DC converters 16 transform DC power between the circuit CR11 and the circuit CR12. Specifically, DC/DC converters 16 step down the DC power from the battery 21, and provide the DC power to the auxiliary battery 17 and other auxiliary devices connected to the circuit CR12. The capacity of the battery 21 is larger than the capacity of the auxiliary battery 17.

The battery pack 20A and/or the battery pack 20B are/is attached to the vehicle body 10 by connecting the terminals T21, T22 of the battery pack 20A to the terminals T11A, T12A or connecting the terminals T21, T22 of the battery pack 20B to the terminals T11B, T12B, thereby configuring the vehicle 100. In the vehicle 100, a communication line CL1 of the vehicle body 10, a communication line CL2 of the battery pack 20A, and a communication line CL2 of the battery pack 20B are connected. These communication lines constitute an in-vehicle network of the vehicle 100.

Each of DC inlet 14b and AC inlet 15b has a terminal for detecting connection/disconnection of the charging cable (plug), and outputs a signal indicating whether or not the charging cable is connected to ECU 18b. ECU 18a acquires information indicating the inlet state from ECU 18b, and transmits a control command to ECU 18c. AC charger 15a performs AC/DC transformation. The plug-in charge of the batteries 21 is executed by cooperation of ECUs 18a and 18c.

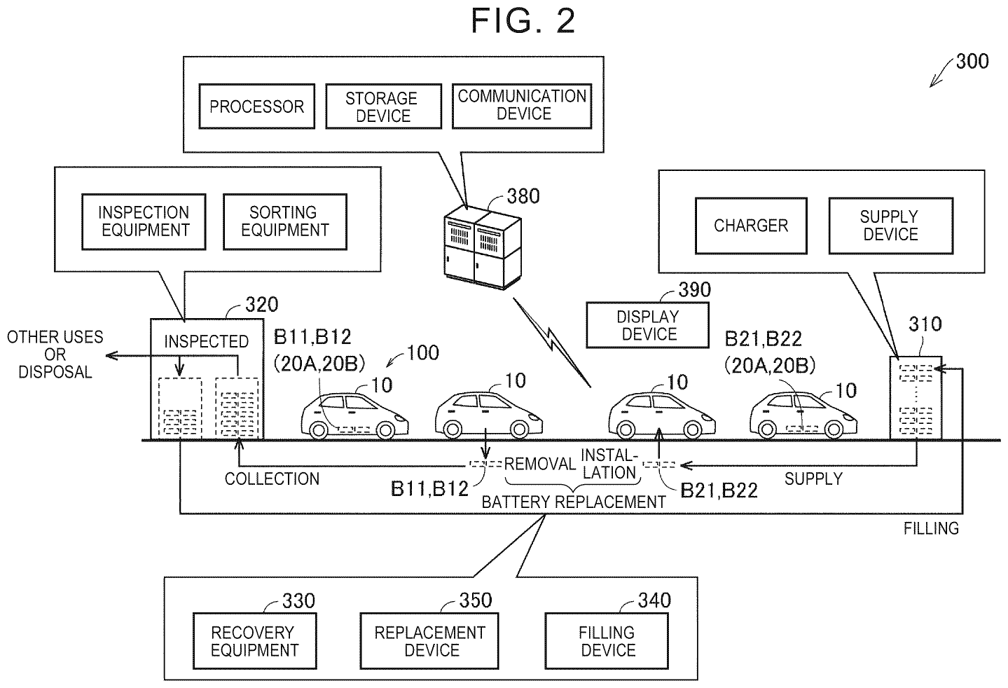

The vehicle body 10 further includes a Human Machine Interface (HMI) 19a and a communication device 19b. HMI 19a and the communication device 19b are also supplied with electric power from the auxiliary battery 17. HMI 19a includes an input device and a display device provided in the vehicle cabin. HMI 19a may include a touch panel display. The input device outputs a signal corresponding to an input from the user to ECU 18a. The communication device 19b is configured to be capable of wirelessly communicating with servers 380 (FIG. 2) described later. In addition, various sensors (typically referred to as in-vehicle sensor 19c) that are not illustrated are also mounted on the vehicle body 10. ECU 18a is configured to acquire the detections of these sensors, either directly or via other ECUs.

In this embodiment, HMI 19a includes an activation switch. In general, the activation switch is referred to as a “power switch” or an “ignition switch” or the like. The user of the vehicle 100 can activate or deactivate the control system (including ECU) of the vehicle 100 or turn the vehicle 100 Ready-ON or Ready-OFF by operating the activation switch.

Ready-ON state is a state in which the voltage of at least one battery 21 of the battery pack 20A, 20B connected to the vehicle body 10 is applied to the circuit CR11 of the vehicle body 10. In Ready-ON state, SMR 13 is in the closed state, and at least one SMR 23 of the battery-pack 20A, 20B is also in the closed state. Power is supplied from the batteries 21 corresponding to the closed SMR 23 to the vehicle-driven devices (MG 11a and inverter 11b). Ready-OFF state is a state in which the voltage of the battery 21 is not applied to the circuit CR11. In Ready-OFF state, SMR 13 is in the open state, and no electric power is supplied to the vehicle-driven device from any of the batteries 21 in the battery-pack 20A, 20B.

The battery pack 20A, 20B mounted on the vehicles 100 can be replaced with another battery pack. FIG. 2 is a diagram illustrating an example of a configuration of a battery replacement system for replacing a battery pack. The battery replacement system 300 shown in FIG. 2 is implemented in, for example, a battery exchange station.

Referring to FIG. 2, the battery replacement system 300 is configured to remove a battery pack mounted on the vehicle 100 from the vehicle body 10 and attach another battery pack to the vehicle body 10. Two battery packs (battery pack 20A and 20B) are simultaneously removed from the vehicle 100, and two alternative battery packs are simultaneously attached to the vehicle 100. However, the present disclosure is not limited thereto, and the battery-pack 20A, 20B may be replaced one by one in order. In addition, the replacement of the battery pack includes cases where only one battery pack is mounted at the mounting position of either the battery pack 20A or the battery pack 20B after the two battery packs are removed.

Hereinafter, the two battery packs collected from the vehicle 100 are referred to as “battery pack B11, B12”, and the two battery packs attached to the vehicle 100 instead of the battery packs B11, B12 are referred to as “battery packs B21, B22”. Each of the battery packs B11, B12, B21, B22 has a configuration of the battery pack shown in FIG. 1. The battery packs B21, B22 function as battery packs 20A, 20B (FIG. 1) in the vehicles 100.

Specifically, the battery replacement system 300 includes a first storage device 310, a second storage device 320, a recovery device 330, a filling device 340, a replacement device 350, a server 380, and a display device 390. The first storage device 310 stores a plurality of battery packs to be supplied to the vehicle. The first storage device 310 includes a charger and a supply device in addition to a pack storage unit (for example, a storage unit). The second storage device 320 stores a plurality of battery packs collected from a plurality of vehicles. The second storage device 320 includes an inspection device and a sorting device in addition to the pack accommodating portion. The server 380 includes a processor, a storage device, and a communication device, and functions as a control device. The storage device stores information (e.g., specification information) related to the respective battery packs present in the battery replacement system 300 separately by the identification information (pack ID) of the battery packs. The display device 390 displays information in accordance with an instruction from the server 380.

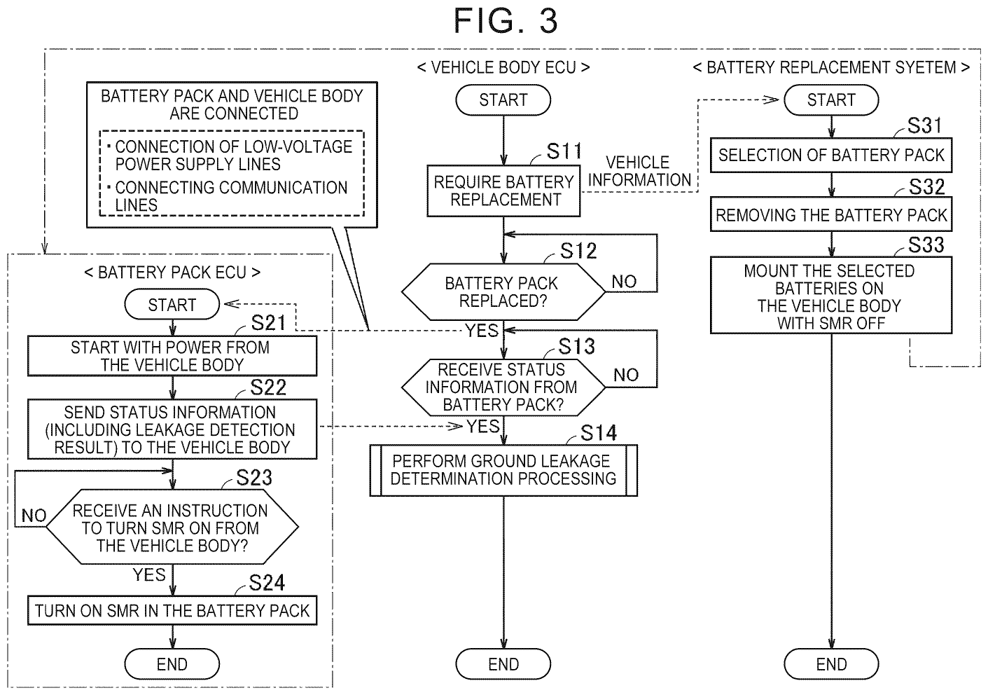

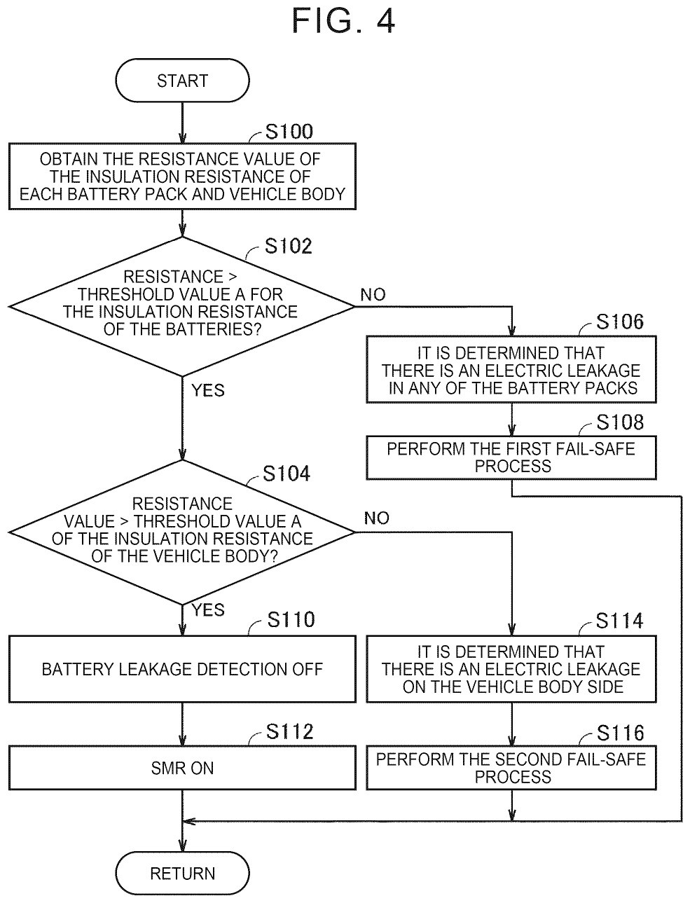

Hereinafter, a battery replacement method will be described with reference to FIGS. 1 to 4. FIG. 3 is a flowchart illustrating an example of a method of replacing a battery pack. FIG. 4 is a flowchart illustrating an example of the electric leakage determination process illustrated in FIG. 3. After the vehicles 100 are parked in a predetermined area in the battery-replacing station, ECU 18a starts S14 process from S11 shown in FIG. 3. The processing flow may be started in response to a request from a terminal (user terminal) of the user of the vehicle 100 or an input device in the vehicle 100. ECU 18a and servers 380 are configured to be wirelessly communicable.

In step (hereinafter, step is referred to as “S”) 10, ECU 18a transmits a signal requesting replacement of the battery pack (hereinafter, referred to as “replacement request signal”) to the servers 380. The replacement request signal includes identification information (vehicle ID) of the vehicle 100 and specification information of battery packs (battery pack B11, B12) mounted on the vehicle 100. The replacement request signal may include the specification information of the vehicle body 10 in place of or in addition to the specification information of the battery-pack B11, B12.

In S12, ECU 18a determines whether or not the battery-pack has been replaced. While the replacement of the batteries is not completed (NO in S12), the determination of S12 is repeatedly performed.

Upon receiving the exchange-request signal, the server 380 starts S33 process from S31 of FIG. 3.

In S31, the server 380 selects a battery pack (stock) stored in the first storage device 310 that matches the specification of the vehicle 100 indicated by the replacement request signal. When it is determined that the battery pack that meets the specifications of the vehicle 100 is not in stock, the server 380 may cause the display device 390 to display a predetermined message and stop the battery replacement process. If S31 selects a battery pack, the process is transferred to S32.

In S32, the servers 380 control the replacement device 350 so that the battery-pack B11, B12 is removed from the vehicle body 10. Accordingly, the vehicle body 10 and the battery-pack B11, B12 are separated from each other. The process is then transferred to a S33.

In S33, the servers 380 control the charger of the first storage device 310 so that the battery-pack B21 or B22 selected by S31 is charged. However, the charging timing can be changed as appropriate. The charged battery pack may be filled in the first storage device 310. When the charging is completed, the servers 380 control the supply device of the first storage device 310 so that the battery-pack B21 or B22 is conveyed (supplied) from the first storage device 310 to the replacement device 350. Subsequently, the servers 380 control the replacement device 350 so that the battery-pack B21 or B22 is attached to the vehicle body 10. At this time, SMR 23 of the attached battery-pack B21 or B22 is opened. Thereafter, the server 380 transmits a signal indicating completion of the installation of the battery pack (hereinafter, referred to as a “replacement completion signal”) to ECU 18a.

FIG. 2 illustrates an example in which removal of the battery pack and attachment of the battery pack are performed at different positions. The vehicle position may be adjusted prior to removal of the battery pack, prior to installation of the battery pack, or both. A conveyance device (for example, a conveyance device of a conveyor type) or a conveyance robot (not shown) may move the vehicle. Removal of the battery pack and attachment of the battery pack may be performed at the same position. The battery pack may be replaced (removed and attached) while the vehicle is stationary. The transport method of each of the recovery device 330, the supply device, and the filling device 340 is also arbitrary. These conveyance methods may be a conveyor method or a method using a conveyance robot. Note that the battery pack (power storage device) may be manually replaced by the user without communication between the battery replacement system (station) and the vehicle.

For example, when the battery pack B21, B22 is attached to the vehicle body 10, the terminal T21, T22 of the battery pack B21 are connected to the terminal T11A, T12A of the vehicle body 10, and the terminal T21, T22 of the battery pack B22 are connected to the terminal T11B, T12B of the vehicle body 10, so that the connection shown in FIG. 1 is established. When the battery pack B21, B22 is attached to the vehicle body 10, the circuit CR12, CR22 and the communication line CL1, CL2 are connected between the vehicle body 10 and each of the battery packs B21, B22. Then, in each of the battery-pack B21, B22, S24 process is started from S21 shown in FIG. 3.

In S21, ECU 28a is activated by electric power supplied from a power source (auxiliary battery 17) in the vehicle body 10. The process is then transferred to a S22.

In S22, ECU 28a transmits information indicating the state of the battery pack (hereinafter, referred to as “state information”) to ECU 18a. The status information includes, for example, information about the present voltage of the battery 21 detected by BMS 22a. Note that the state information may include information about the leakage detection result (leakage state) detected by the leakage detector 22b and the leakage ECU 28b. The voltage of the battery 21 may vary depending on State Of Charge (SOC of the battery 21). SOC represents, for example, a ratio of the present amount of stored electricity to the amount of stored electricity in a fully charged state from 0 to 100%. The process is then transferred to a S23.

In S23, ECU 28a determines whether or not a SMR on-command has been received from the vehicle body 10. ECU 28a waits for a SMR on-command from the vehicle body 10 in S23 while keeping SMR 23 open. When ECU 28a receives SMR on-command (YES in S23), the process proceeds to S24.

In S24, ECU 28a switches SMR 23 from the open state (shut-off state) to the closed state (connected state).

On the other hand, when the battery-pack B21, B22 is attached to the vehicle body 10, ECU 18a receives a replacement completion signal (S33) from the servers 380. As a result, it is determined that S12 is YES, and the process proceeds to S13.

In S13, ECU 18a determines whether the status data is received from ECU 28a of the battery-pack B21 or B22. When ECU 18a receives the status information from the battery pack (YES in S13), the process is transferred to S14.

In S14, ECU 18a executes the electric leakage determination process. Hereinafter, the leakage determination process will be described with reference to the flowchart of FIG. 4.

In S100, ECU 18a acquires the resistance values of the respective battery-packs 20A, 20B and the insulation resistance of the vehicle body 10. ECU 18a may acquire the resistance value of the insulation resistance from the status information received from ECU 28a of the battery-pack 20A, 20B, or may acquire the resistance value of the insulation resistance from ECU 28b. Further, ECU 18a acquires the resistance of the insulation resistance of the vehicle body 10 from ECU 18d. The process is then transferred to a S102.

In S102, ECU 18a determines whether or not the resistivity of the insulating resistances of the respective battery-packs 20A, 20B is greater than the threshold value α. The threshold value α is a predetermined value for determining the presence or absence of an electric leakage, and is adapted by an experiment or the like. If both are determined to be greater than threshold a (YES at S102), then the process moves to S104.

In S104, ECU 18a determines whether or not the resistance value of the insulation resistance of the vehicle body 10 is larger than the threshold value α. Since the threshold value α is as described above, the detailed description thereof will not be repeated. Note that the threshold used in S102 process may differ from the threshold used in S104 process. If it is determined that the value is greater than the threshold value α (YES in S104), the process proceeds to S110. When at least one of the resistivity values of the insulating resistances of the battery-pack B21, B22 is equal to or less than the threshold value α (NO in S102), the process is transferred to S106.

In S106, ECU 18a determines that there is an electric leakage in the battery pack in which the resistance value of the insulating resistance of the battery pack 20A, 20B is equal to or less than the threshold value α. ECU 18a sets, for example, a flag associated with the pack ID of the battery pack in which the resistance value of the insulation resistance is equal to or less than the threshold value α to the ON-state. The process is then transferred to a S108.

In S108, ECU 18a performs a first fail-safe process. The first fail-safe process may include at least one of a process of controlling SMR 23 of the battery pack of the pack ID corresponding to the flag of the ON state to the OFF state, a process of prohibiting the switching of SMR 23 to the ON state, a process of controlling SMR 13 to the OFF state, and a process of prohibiting the switching of SMR 13 to the ON state. The process is then terminated.

In S110, ECU 18a sets the electric leakage detection of the battery-pack 20A, 20B to the off-state. Specifically, ECU 18a switches off the circuit (leakage detector 22b) for detecting the resistivity of the insulating resistor of each of the battery-pack 20A, 20B and sets the circuit to a state in which the leakage cannot be detected (detection stopped state). The process is then transferred to a S112.

In S112, ECU 18a sets SMR to the on-state. ECU 18a transmits a SMR on-command to SMR 13 and SMR 23 of the battery-pack 20A, 20B. The process is then terminated. When it is determined that the resistance value of the insulation resistance of the vehicle body 10 is equal to or less than the threshold value α (NO in S104), the process proceeds to S114.

In S114, ECU 18a determines that there is an electric leakage in the vehicle body 10. For example, ECU 18a sets a flag indicating that there is an electric leakage in the vehicle body 10 to an on-state. The process is then transferred to a S116.

In S116, ECU 18a performs a second fail-safe process. The second fail-safe process may include a process of controlling SMR 13 to the off state, a process of prohibiting the switching of SMR 13 to the on state, a process of prohibiting the switching of SMR 23 of the battery-pack 20A, 20B to the on state, and the like. The process is then terminated.

Note that ECU 18a may detect leakage at the time of Ready-OFF in the respective battery packs.

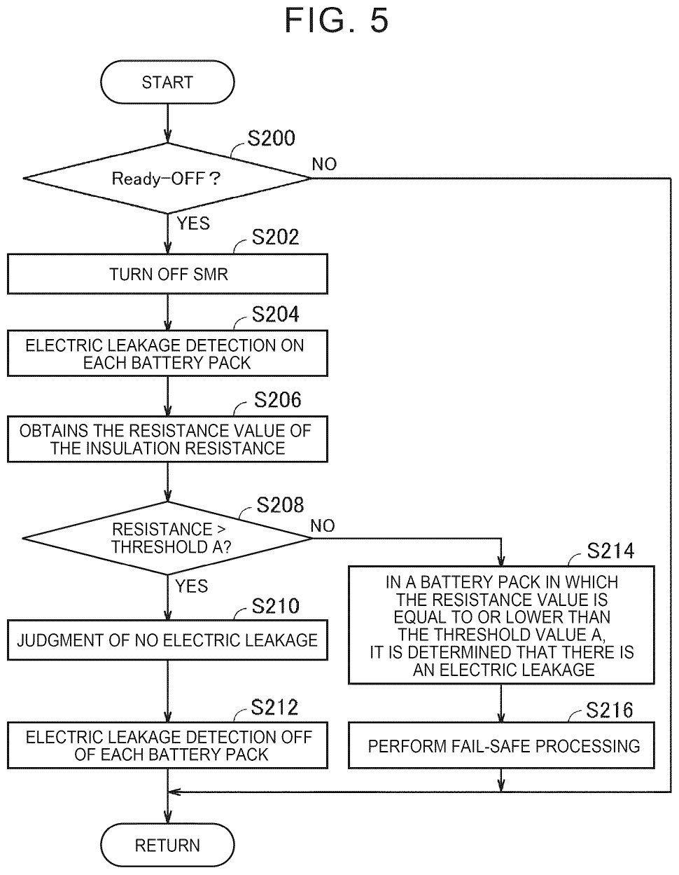

Hereinafter, the electric leakage determination process at the time of Ready-OFF will be described referring to FIG. 5. FIG. 5 is a flow chart illustrating an exemplary leakage determination process at the time of Ready-OFF.

In S200, ECU 18a determines whether or not it is at the time of Ready-OFF. ECU 18a may determine that it is at the time of Ready-OFF after the operation (off operation) of the start switch is accepted at the time of Ready-ON and when the operation (on operation) of the start switch is not accepted thereafter. If it is determined that the time is Ready-OFF time (YES in S200), the process proceeds to S202.

In S202, ECU 18a turns off SMR 23 of SMR 13 and the battery-pack 20A, 20B. The process is then transferred to a S204.

In S204, ECU 18a sets the electric leakage detection of the respective battery-packs 20A, 20B to the on-state. The process is then transferred to a S206.

In S206, ECU 18a acquires the resistance of the insulating resistance from the respective battery-packs 20A, 20B. The process is then transferred to a S208.

In S208, ECU 18a determines whether or not the resistivity of the insulating resistances of the respective battery-packs 20A, 20B is greater than the threshold value α. If it is determined that the value is greater than the threshold value α (YES in S208), the process proceeds to S210.

In S210, ECU 18a determines that all of the battery-pack 20A, 20B have no electric leakage. The process is then transferred to a S212.

In S212, ECU 18a sets the ground fault detection to the off-state. The process is then terminated. If it is determined that at least one of the resistance values of the insulation resistance of the battery-pack 20A, 20B is equal to or less than the threshold value a (NO in S208), the process proceeds to S214.

In S214, ECU 18a determines that there is an electric leakage in the battery pack in which the resistance value of the insulation resistance is equal to or less than the threshold value α. ECU 18a sets, for example, a flag associated with the pack ID of the battery pack in which the resistance value of the insulation resistance is equal to or less than the threshold value α to the ON-state. The process is then transferred to a S216.

At S216, ECU 18a performs a fail-safe process. The fail-safe process may include at least one of a process of controlling SMR 23 of the battery pack of the pack ID corresponding to the flag of the ON state to the OFF state, a process of prohibiting the switching of SMR 23 to the ON state, a process of controlling SMR 13 to the OFF state, and a process of prohibiting the switching of SMR 13 to the ON state. The process is then terminated.

In this way, the presence or absence of an electric leakage can be detected in the respective battery-packs 20A, 20B when SMR 13 is shut off at the time of Ready-OFF in the vehicle 100.

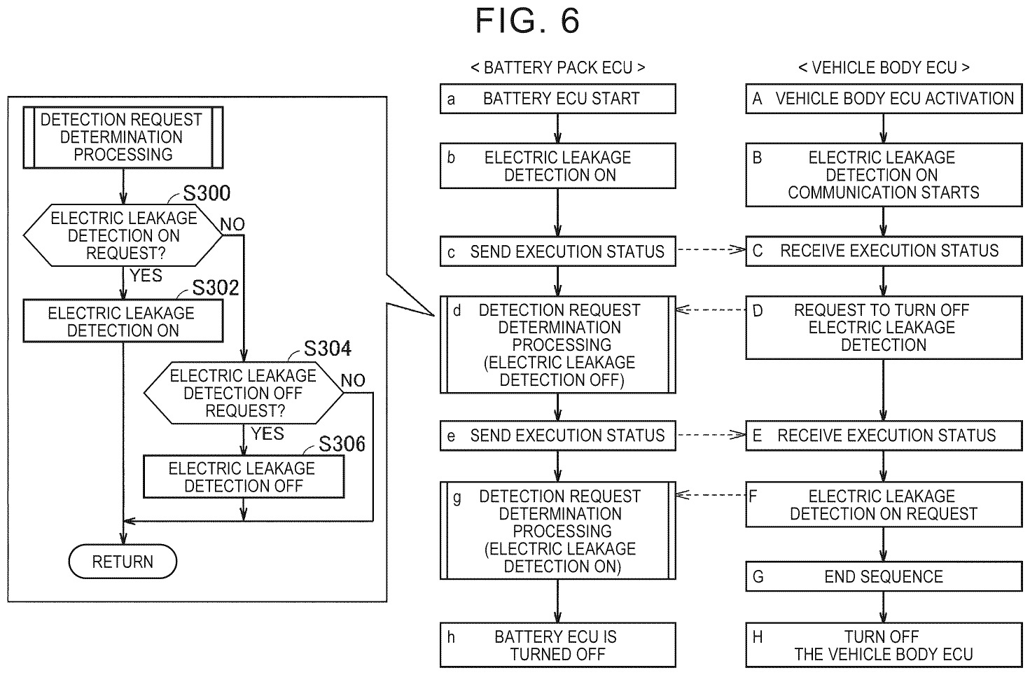

Various types of information are communicated between the vehicle body 10 and each battery pack. Specifically, ECU 28a transmits, to ECU 18a of the vehicle body 10, information on whether the electric leakage detection of the respective battery packs is in the on-state or the off-state, and information on the resistance of the insulation resistance. On the other hand, ECU 18a transmits to ECU 28a one of a request to set the leakage detection to the ON state and a request to set the leakage detection to the OFF state. ECU 28a of the batteries sets the leakage detection to either the on-state or the off-state in response to a request from ECU 18a. In the following, referring to FIG. 6, an exemplary process in which ECU 18a (vehicle body ECU) requests ECU 28a (battery ECU) of the respective battery packs to execute the leakage detection will be described. FIG. 6 is a flowchart illustrating an example of a process of setting a state of electric leakage detection.

As shown in “A” of FIG. 6, for example, when ECU 18a is activated and ECU 28a is activated as shown in “a” of FIG. 6.

As illustrated in “B” of FIG. 6, ECU 18a sets the electric leakage detection of the vehicle body 10 to the ON state (the leakage detector 12 is in the ON state), and starts communication with ECU 28a. As illustrated in “b” of FIG. 6, ECU 28a sets the leakage detection of the battery pack 20 to the ON state, and transmits an execution state indicating that the leakage detection is the ON state to ECU 18d as illustrated in “c” of FIG. 6.

As illustrated in “C” of FIG. 6, when the execution status is received in ECU 18a, as illustrated in “D” of FIG. 6, ECU 28a is required to turn off the electric leakage detection of the battery pack 20.

As illustrated in “d” of FIG. 6, a detection-request determination process is executed in ECU 28a. Detection request determination process, as shown in the left flow chart of FIG. 6, a step of determining whether there is a leakage detection ON request (S300), when there is a request for leakage detection ON (YES in S300), a step of setting the leakage detection ON to the ON state (S302), if there is no request for leakage detection ON (NO in S300), a step of determining whether there is a leakage detection OFF request (S304), if there is a leakage detection OFF request (YES in S304), and a step of setting the leakage detection to the OFF state (S306). Therefore, when an off-request for the electric leakage detection is received from ECU 18a, the electric leakage detection is set to the off-state.

As illustrated in “e” of FIG. 6, when the execution status indicating that the leakage detection is in the off-state is transmitted from ECU 28a, the execution status is received in ECU 18a as illustrated in “E” of FIG. 6. Thereafter, when SMR 13 is set to the off-state at the time of Ready-OFF or the like, ECU 28a is required to turn on the electric leakage detection in the battery pack 20 as illustrated in “F” of FIG. 6.

As illustrated in “f” of FIG. 6 and “g” of FIG. 6, the detection-request determination process is executed in ECU 28a, the leakage detection is set to the ON state, and ECU 28a is turned to the OFF state after the leakage detection is performed. On the other hand, in ECU 18a, as illustrated in “G” of FIG. 6 and “H” of FIG. 6, the termination sequence is executed, and ECU 18a is turned off. ECU 18a can prevent the leakage detection from interfering between the battery pack 20A, 20B and between the battery pack 20 and the vehicle body 10 by setting the timing at which the leakage detection of the battery pack 20A, 20B is turned on by using the execution status. For example, ECU 18a transmits the above-described demand to ECU 28a at the timing of turning on/off the leakage detection in the flow charts of FIGS. 3 and 4. ECU 18a may request the change of the state of the electric leakage detection of the battery-pack 20A, 20B by using the state of the electric leakage detection of the vehicle body 10.

As described above, according to the vehicle 100 of the present embodiment, the presence or absence of electric leakage between the battery pack 20A, 20B and the electric device of the vehicle body 10 is detected by ECU 28b and ECU 18d while the battery pack 20A, 20B and the electric device of the vehicle body 10 are electrically disconnected from each other. Therefore, the presence or absence of an electric leakage is accurately detected in each of the battery-pack 20A, 20B and the vehicle body 10. Furthermore, the presence or absence of an electric leakage between the battery pack 20A, 20B and the electric device of the vehicle body 10 is detected by ECU 18d while the battery pack 20A, 20B and the electric device of the vehicle body 10 are electrically connected to each other. Since the electric leakage detection of the battery pack 20A, 20B is set to the off-state, it is possible to detect the presence or absence of an electric leakage in a state in which the battery pack 20A, 20B and the electric device of the vehicle body 10 are connected, while avoiding interference between the electric leakage detection using ECU 28b of the battery pack 20 and the electric leakage detection using ECU 18d. As described above, since the electric leakage is detected in accordance with the state of attachment and detachment of the battery-pack 20A, 20B, it is possible to identify the location where the electric leakage occurs while avoiding the interference. Therefore, it is possible to provide a vehicle that appropriately detects an electric leakage when a plurality of electric leakage detection devices is mounted.

Modification examples will be described below.

In the embodiments described above, although the vehicles 100 are shown as one case of mounting two battery pack 20A, 20B, the number of mounting battery packs may be one or three or more.

Furthermore, in the above-described embodiment, the case where the execution subject of the leakage determination process is ECU 18a has been described as an example, but the execution subject of the leakage determination process or the switching subject of SMR 13, 23 is not limited to ECU 18a, and may be, for example, ECU 18d or another ECU mounted on the vehicle body 10.

Further, the configuration of the vehicle body shown in FIG. 1 can be changed as appropriate. For example, SMR 13 of the vehicle body 10 may be omitted, or SMR 23 of the battery-pack 20 may be omitted. In addition, at least one of DC inlet 14b and AC inlet 15b may be omitted, or may be changed to one inlet shared by AC/DC. These inlets may be configured to be capable of bidirectional power transfer. The vehicle body may perform an external power supply (Vehicle to Everything: V2X) using the electric power outputted from the attached battery pack.

All or some of the above-mentioned modified examples may be combined for implementation.

It should be considered that the embodiments disclosed above are for illustrative purposes only and are not limitative of the disclosure in any aspect. The scope of the disclosure is represented by the appended claims, not by the above description, and includes all modifications within the meanings and scope equivalent to the claims.

What is claimed is:

1. A vehicle comprising:
a vehicle body;
a battery detachable from the vehicle body;
a first detection device provided in the battery to detect presence or absence of an electric leakage; and
a second detection device provided on the vehicle body to detect presence or absence of an electric leakage, wherein
each of the first detection device and the second detection device detects the presence or absence of the electric leakage when in a first state in which the battery and an electric device of the vehicle body are electrically disconnected from each other, and
the second detection device detects the presence or absence of the electric leakage when in a second state in which the battery and the electric device are electrically connected to each other.

2. The vehicle according to claim 1, wherein the second detection device detects the presence or absence of the electric leakage when in the second state and while detection of the presence or absence of the electric leakage by the first detection device is stopped.

3. The vehicle according to claim 1, further comprising a control device that acquires information about a detection result of the presence or absence of the electric leakage from the first detection device and the second detection device, wherein:
when in the second state, the control device acquires an execution status of detection of the electric leakage; and
the control device either requests detection of the electric leakage by the first detection device or requests stop of detection of the electric leakage using the acquired execution status.
